(19) United States
(12) Patent Application Publication
(10) Pub. No.: US 2025/0183142 A1
(43) Pub. Date: Jun. 5, 2025

(54) CIRCUIT BOARD AND ELECTRONIC COMPONENT PACKAGE

(71) Applicant: SAMSUNG ELECTRO-MECHANICS CO., LTD., Suwon-si (KR)

(72) Inventor: Sang-Min Lee, Suwon-si (KR)

(73) Assignee: SAMSUNG ELECTRO-MECHANICS CO., LTD., Suwon-si (KR)

(21) Appl. No.: 18/815,194

(22) Filed: Aug. 26, 2024

(30) Foreign Application Priority Data
Dec. 5, 2023 (KR) 10-2023-0174336

(51) Int. Cl. H01L 23/498; H01L 23/00

(52) U.S. Cl. CPC H01L 23/49822; H01L 23/49816; H01L 24/16; H01L 2224/16238

(57) ABSTRACT

A circuit board including an insulating layer burying at least one wiring layer and at least one via layer, and having first and second surfaces facing each other in a first direction, and a pad including a protruding portion protruding from the first surface of the insulating layer and an embedded portion embedded in the insulating layer, and electrically connected to the wiring layer. The protruding portion includes a first portion positioned at the outermost part along the first direction and parallel to a second direction parallel to the first surface, and a second portion connected to the embedded portion and adjacent to the first surface, and in the width along the second direction, the width of the first portion is different from the width of the second portion.

### CROSS-REFERENCE TO RELATED APPLICATION

This application claims priority to and the benefit of Korean Patent Application No. 10-2023-0174336 filed in the Korean Intellectual Property Office on Dec. 5, 2023, the entire contents of which are incorporated herein by reference.

### BACKGROUND

### (a) Technical Field

The present disclosure relates to a circuit board and an electronic component package.

### (b) Description of the Related Art

Recently, as semiconductors have become high-performance, there is a trend to mount memory, passive devices such as MLCC and IPD on one board, and to make the board thinner.

However, in the case of such a board, bending defects may occur, which may lead to reliability issues, such as a deterioration in the adhesion between the pad and the insulating layer.

Accordingly, there is a need to develop a circuit board capable of implementing high reliability by improving the adhesion between the pad and the insulating layer.

### SUMMARY

The present disclosure attempts to provide a circuit board capable of reducing the risk of cracks occurring in the pad, improving reliability, improving adhesion between the insulating layer and the pad, and reducing the risk of delamination defects, and an electronic component package including the same. However, embodiments of the present disclosure are not limited to those mentioned above, and may be variously extended in the scope of the technical ideas included in the present disclosure.

A circuit board according to an embodiment includes: an insulating layer burying at least one wiring layer and at least one via layer, the insulating layer having first and second surfaces facing each other in a first direction; and a pad including a protruding portion protruding from the first surface of the insulating layer and an embedded portion embedded in the insulating layer, the pad electrically connecting to the wiring layer, wherein the protruding portion includes a first portion positioned at an outermost part along the first direction and substantially parallel to a second direction that is parallel to the first surface; and a second portion connected to the embedded portion and adjacent to the first surface, and along the second direction, a width of the first portion is different from a width of the second portion.

The width of the first portion may be smaller than the width of the second portion.

The protruding portion may further include a third portion connecting the first portion and the second portion, and at least a part of the third portion may have a round shape having a width that increases from the first portion to the second portion.

At least a portion of the third portion may have a convex shape that curves outward of the protruding portion.

The embedded portion may include a fourth portion positioned opposite the first portion of the protruding portion in the first direction and substantially parallel to the second direction, and a fifth portion connecting the fourth portion and the protruding portion, and the fourth portion and the fifth portion may be in contact with the insulating layer.

The fourth portion and the fifth portion of the embedded portion may have surface roughness.

The second portion of the protruding portion may include a first region in contact with the insulating layer and a second region in contact with the embedded portion.

The first region of the second portion of the protruding portion may have surface roughness.

Central axes of the embedded portion and the protruding portion may coincide.

The embedded portion and the protruding portion may include the same material.

An electronic component package according to an embodiment includes: an insulating layer burying at least one wiring layer and at least one via layer, the insulating layer having first and second surfaces facing each other in a first direction; a pad including a protruding portion protruding from the first surface of the insulating layer and an embedded portion embedded in the insulating layer, the pad electrically connecting to the wiring layer; and an electronic component disposed on the insulating layer and electrically connected to the pad, wherein the protruding portion includes a first portion positioned at an outermost part along the first direction and substantially parallel to a second direction that is parallel to the first surface; and a second portion connected to the embedded portion and adjacent to the first surface, and along the second direction, a width of the first portion is different from width of the second portion.

The width of the first portion may be smaller than the width of the second portion.

The protruding portion may include a third portion connecting the first portion and the second portion, and at least a part of the third portion may have a round shape having a width that increases from the first portion to the second portion.

At least a part of the third portion may have a convex shape that curves outward of the protruding portion.

The embedded portion may include a fourth portion positioned opposite the first portion of the protruding portion in the first direction and substantially parallel to the second direction; and a fifth portion connecting the fourth portion and the protruding portion, and the fourth portion and the fifth portion may be in contact with the insulating layer.

The fourth portion and the fifth portion of the embedded portion may have surface roughness.

The second portion of the protruding portion may include a first region in contact with the insulating layer and a second region in contact with the embedded portion.

The first region of the second portion of the protruding portion may have surface roughness.

Central axes of the embedded portion and the protruding portion may coincide.

A connecting portion, which is disposed between the electronic component and the pad to electrically connect the electronic component and the wiring layer, may be included.

According to the circuit board and the electronic component package including the same according to the embodiment, it is possible to reduce the risk of cracks occurring in the pad, improve reliability, improve adhesion between the insulating layer and the pad, and reduce the risk of delamination defects.

### BRIEF DESCRIPTION OF THE DRAWINGS

FIG. 1 is a cross-sectional view schematically showing a circuit board according to an embodiment.

FIG. 2 is an enlarged view of portion A in FIG. 1.

FIGS. 3 to 11 are cross-sectional views showing a method of manufacturing a circuit board according to an embodiment.

FIG. 12 is a cross-sectional view schematically showing an electronic component package according to an embodiment.

### DETAILED DESCRIPTION

Hereinafter, the present disclosure will be described in detail hereinafter with reference to the accompanying drawings, in which embodiments of the present disclosure are shown. The drawings and description are to be regarded as illustrative in nature and not restrictive. Like reference numerals designate like elements throughout the specification. In the accompanying drawings, some constituent elements are exaggerated, omitted, or schematically illustrated, and the size of each constituent element does not entirely reflect the actual size.

The accompanying drawings are intended only to facilitate an understanding of the exemplary embodiments disclosed in this specification, and it is to be understood that the technical ideas disclosed herein are not limited by the accompanying drawings and include all modifications, equivalents, or substitutions that are within the range of the ideas and technology of the present disclosure.

Although terms of “first,” “second,” and the like are used to explain various constituent elements, the constituent elements are not limited to such terms. These terms are only used to distinguish one constituent element from another constituent element.

In addition, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is referred to as being “on” or “above” a reference element, it can be positioned above or below the reference element, and it is not necessarily referred to as being positioned “on” or “above” in a direction opposite to gravity.

Throughout the specification, the terms “comprise” or “have” are intended to specify the presence of stated features, integers, steps, operations, constituent elements, components or a combination thereof, but do not preclude the presence or addition of one or more other features, integers, steps, operations, constituent elements, components, and/or groups thereof. Therefore, unless explicitly described to the contrary, the term “comprise” and variations such as “comprises” or “comprising” will be understood to imply the inclusion of stated elements but not the exclusion of any other elements.

In addition, the phrase “on a plane” means a view from a position above the object (e.g., from the top), and the phrase “on a cross-section” means a view of a cross-section of the object which is vertically cut from the side.

Throughout the specification, the term “coupled” does not mean only that “directly or physically coupled”, but also mean that “indirectly or contactlessly coupled” with another element in between.

Throughout the specification, the term “connected” does not mean only that two or more constituent components are directly connected, but may also mean that two or more constituent components are indirectly connected through another constituent component, that two or more components are electrically connected as well as physically connected, or that two or more constituent components are referred to by different names but are united by location or function.

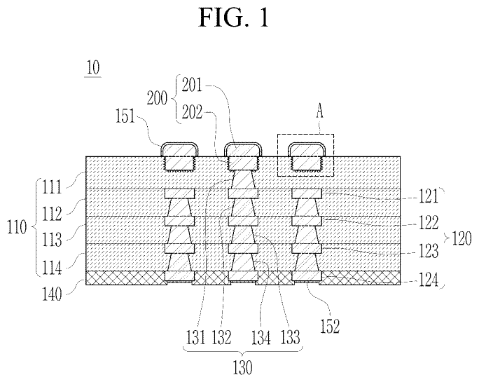

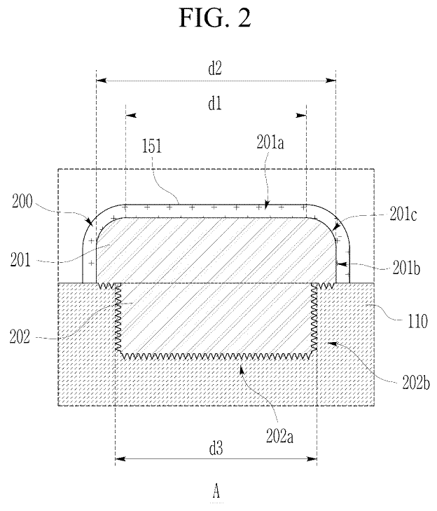

Hereinafter, a circuit board according to an embodiment will be described with reference to FIGS. 1 and 2.

FIG. 1 is a cross-sectional view schematically showing a circuit board according to an embodiment, and FIG. 2 is an enlarged view of portion A in FIG. 1.

Referring to FIG. 1, a circuit board 10 according to the present embodiment includes an insulating layer 110 burying at least one wiring layer and at least one via layer, and having first and second surfaces facing each other in a first direction; and a pad 200 including a protruding portion 201 protruding from a first portion 201a of the insulating layer 110 and an embedded portion 202 embedded in the insulating layer 110, and electrically connected to a wiring layer 120. The protruding portion 201 may include the first portion 201a positioned at the outermost part along the first direction and parallel to a second direction parallel to the first surface; and a second portion 201b adjacent to the embedded portion 202 and protruding from the first surface, and along the second direction, a width d1 of the first portion 201a may be different from a width d2 of the second portion 201b. The first portion 201a may be substantially parallel to the second direction. As used herein, “substantially parallel” may mean that the first portion 201a deviates 1° or less, including 0°, from the second direction.

The circuit board 10 according to the present embodiment may include the insulating layer 110. The insulating layer 110 may include at least one insulating layer selected from first to fourth insulating layers 111, 112, 113 and 114. For example, the insulating layer 110 may include first to fourth insulating layers 111, 112, 113 and 114. A third insulating layer may be positioned on the fourth insulating layer 114. The second insulating layer 112 may be positioned on the third insulating layer 113. The first insulating layer 111 may be positioned on the second insulating layer 112.

An insulating material may be used as the material for each insulating layer 110, and the insulating material may include a thermosetting resin such as an epoxy resin, a thermoplastic resin such as polyimide, or these resins that include inorganic fillers such as silica and reinforcing materials such as glass fiber. For example, materials such as prepreg, resin coated copper foil (RCC), may be used for the insulating layer 110, but are not limited thereto, and materials that do not include reinforcements such as glass fiber, for instance, Ajinomoto-build up film (ABF), may also be used. If necessary, a photosensitive insulating material such as photo imageable dielectric (PID) may be used as a material for the insulating layer 110.

Referring to FIG. 1, the insulating layer 110 is shown to include four layers, but it is not limited thereto, and the insulating layer 110 may include more layers than shown, or may include fewer layers.

The circuit board 10 according to the present embodiment may include the wiring layer 120. The wiring layer 120 may include at least one wiring layer selected from first to fourth wiring layers 121, 122, 123 and 124. For example, the wiring layer 120 may include first to fourth wiring layers 121, 122, 123 and 124. The wiring layer 120 may be positioned on one surface of the insulating layer 110. The first wiring layer 121 may be positioned on one surface of the first insulating layer 111. The second wiring layer 122 may be positioned on one surface of the second insulating layer 112. The third wiring layer 123 may be positioned on one surface of the third insulating layer 113. The fourth wiring layer 124 may be positioned on one surface of the fourth insulating layer 114.

The wiring layer 120 may transmit signals of the circuit board 10. A metal material may be used as a material for the wiring layer 120. Metal materials may include copper (Cu), aluminum (AI), silver (Ag), tin (Sn), gold (Au), nickel (Ni), lead (Pb), titanium (Ti), or alloys thereof. The wiring layer 120 may perform various functions depending on the design, such as ground pattern, power pattern, signal pattern, etc. Each of these patterns may have a shape such as a line or a plane. In the case of the fourth wiring layer 124 positioned in the outermost layer of the wiring layer 120, it may function for connection to other substrates or components.

Referring to FIG. 1, the wiring layer 120 is shown as including first to fourth wiring layers 121, 122, 123 and 124, but it is not limited thereto, and may have more wiring layers than shown, and may have fewer wiring layers.

The circuit board 10 according to the present embodiment may include the pad 200. Pad 200 may be positioned on one surface of the insulating layer 110. The pad 200 may include a protruding portion 201 protruding from the insulating layer 110 and an embedded portion 202 embedded in the insulating layer 110. The pad 200 may be electrically connected to the wiring layer 120. For example, the pad 200 may be positioned on one surface of the first insulating layer 111. The embedded portion 202 of the pad 200 may be embedded in the first insulating layer 111, and the remaining portion, which is the protruding portion 201, may protrude from one surface of the first insulating layer 111.

A metal material may be used as a material for the pad 200. A metal material may include copper (Cu), aluminum (AI), silver (Ag), tin (Sn), gold (Au), nickel (Ni), lead (Pb), titanium (Ti), or alloys thereof.

The circuit board 10 according to the present embodiment may include a via layer 130. The via layer 130 may be disposed to electrically connect the first to fourth wiring layers 121, 122, 123 and 124 to each other. The via layer 130 may include at least one via layer selected from first to fourth via layers 131, 132, 133 and 134. The insulating layer 110 may embed at least one via layer selected from first to fourth via layers 131, 132, 133 and 134. For example, the via layer 130 may include first to fourth via layers 131, 132, 133 and 134.

Each via electrode of the via layer 130 may have a tapered shape where the width of one surface is larger than the width of the other surface. A metal material may be used as a material for the via layer 130. Metal materials include copper (Cu), aluminum (AI), silver (Ag), tin (Sn), gold (Au), nickel (Ni), lead (Pb), titanium (Ti), or alloys thereof.

The via layer 130 may include signal vias, ground vias, power vias, etc. depending on the design. The via electrode of the via layer 130 may be one in which each via hole is completely filled with a metal material, or may be one in which the metal material may be formed along the wall of the via hole. The via layer 130 may be formed through a plating process, for example, an additive process (AP), semi AP (SAP), modified SAP (MSAP), or tenting (TT) process. The via layer 130 may include a seed layer that is an electroless plating layer and an electrolytic plating layer formed based on the seed layer.

The first via layer 131 may be positioned in the first insulating layer 111. The first via layer 131 may penetrate the first insulating layer 111 and be connected to the pad 200 and the first wiring layer 121. Accordingly, the first via layer 131 may electrically connect the pad 200 and the first wiring layer 121.

The second via layer 132 may penetrate the second insulating layer 112 and be connected to the first wiring layer 121 and the second wiring layer 122. Accordingly, the second via layer 132 may electrically connect the first wiring layer 121 and the second wiring layer 122.

The third via layer 133 may penetrate the third insulating layer 113 and be connected to the second wiring layer 122 and the third wiring layer 123. Accordingly, the third via layer 133 may electrically connect the second wiring layer 122 and the third wiring layer 123.

The fourth via layer 134 may penetrate the fourth insulating layer 114 and be connected to the third wiring layer 123 and the fourth wiring layer 124. Accordingly, the fourth via layer 134 may electrically connect the third wiring layer 123 and the fourth wiring layer 124.

Referring to FIG. 1, only the first to third fourth layers 131, 132, 133 and 134 are shown, but it is not limited thereto, and more or fewer via layers may be disposed as needed.

The solder resist layer 140 may be positioned on one surface of the insulating layer 110 to cover a part of the fourth wiring layer 124 to prevent unnecessary short circuits. The solder resist layer 140 may be disposed to expose at least a part of the fourth wiring layer 124. The solder resist layer 140 may include a photosensitive resin material.

A first surface treatment layer 151 may be disposed on the surface of the protruding portion 201. The first surface treatment layer 151 may be formed to prevent an oxide layer from forming on the surface of the pad 200. For example, the first surface treatment layer 151 may be formed through the electroless Ni electroless Pd immersion gold (ENEPIG) method and may include nickel (Ni), palladium (Pd), and gold (Au). However, it is not limited thereto, and the first surface treatment layer 151 may be formed by plating with nickel (Ni), tin (Sn), gold (Au), palladium (Pd), etc., or by coating with an organic solder ability preservative (OSP), etc., using surface treatment methods known in the field of circuit board.

A second surface treatment layer 152 may be disposed on the surface of the fourth wiring layer 124. The second surface treatment layer 152 may be formed to prevent an oxide layer from forming on the surface of the fourth wiring layer 124. For example, the second surface treatment layer 152 may be formed through the ENEPIG method and may include nickel (Ni), palladium (Pd), and gold (Au). However, it is not limited thereto, and the second surface treatment layer 152 may be formed by plating with nickel (Ni), tin (Sn), gold (Au), palladium (Pd), etc., or by coating with an organic solder ability preservative (OSP), etc., using surface treatment methods known in the field of circuit board.

Hereinafter, the pad 200 will be described in detail with reference to FIG. 2.

Referring to FIG. 2, the protruding portion 201 is positioned at the outermost part along the first direction, and may include the first portion 201a parallel to the second direction, and the second portion 201b connected to the embedded portion 202 and adjacent to the first surface. The second direction may be parallel to the first surface and perpendicular to the first direction. The first portion 201a may be positioned at one end of the protruding portion 201 in the first direction. The second portion 201b may be positioned in the other end area of the protruding portion 201 in the first direction. The second portion 201b may be adjacent to the embedded portion 202 and protrude from the first surface. For example, along the second direction, the second portion 201b may have a constant width.

Along the second direction, the width d1 of the first portion 201a may be different from the width d2 of the second portion 201b. Along the second direction, the width d1 of the first portion 201a may be smaller than the width d2 of the second portion 201b. The width d1 of the first portion 201a may be the maximum length, the minimum length, or the average value of the lengths of a plurality of line segments measured from one end to the other end of the first portion 201a in the second direction on the cross-section. The width d2 of the second portion 201b may be the maximum length, the minimum length, or the average value of the lengths of a plurality of line segments measured from one end to the other end of the second portion 201b in the second direction on the cross-section.

The protruding portion 201 may include a third portion 201c connecting the first portion 201a and the second portion 201b. At least a part of the third portion 201c of the protruding portion 201 may gradually decrease in height from the first surface from the first portion 201a to the second portion 201b. At least a part of the third portion 201c of the protruding portion 201 may gradually increase in width in the second direction from the first portion 201a to the second portion 201b. At least a part of the third portion 201c may have a round shape. The upper corner region of the protruding portion 201 may have a round shape. At least a part of the third portion 201c may have a convex shape outward of the protruding portion 201.

The second portion 201b of the protruding portion 201 may include a first region in contact with the insulating layer 110 and a second region in contact with the embedded portion 202. The second region may be an area where the protruding portion 201 is connected to the embedded portion 202. The first area, which is the area where the protruding portion 201 contacts the insulating layer 110, may have uneven regions on the surface. The first region of the protruding portion 201 may have surface roughness. The value of surface roughness can be a positive number. In FIG. 2, the uneven regions are shown as having a sharp shape, but this is an example, and any shape that forms surface roughness in the first region is possible.

The embedded portion 202 may include a fourth portion 202a positioned opposite the first portion 201a of the protruding portion 201 in the first direction and parallel to the second direction, and a fifth portion 202b connecting the fourth portion 202a and the protruding portion 201. The fourth portion 202a may be substantially parallel to the second direction. As used herein, “substantially parallel” may mean that the fourth portion 202a deviates 1° or less, including 0°, from the second direction. The fourth portion 202a may be positioned at one end of the embedded portion 202 in the first direction. The fifth portion 202b may be a side portion connected to the fourth portion 202a. The fourth portion 202a and the fifth portion 202b may be adjacent to the insulating layer.

The fourth portion 202a and the fifth portion 202b may be in contact with the insulating layer 110. The fourth portion 202a and the fifth portion 202b may have uneven regions on their surfaces. The fourth portion 202a and the fifth portion 202b may have surface roughness. The value of surface roughness can be a positive number. In FIG. 2, the uneven regions are shown in a sharp shape, but this is an example, and any shape that forms surface roughness in the fourth portion 202a and the fifth portion 202b is possible.

A width d3 of the embedded portion 202 may be constant at the top and bottom. In other words, the width of the fourth portion 202a and the width on the side adjacent to the protruding portion 201 may be the same or similar. The width d3 of the embedded portion 202 may be the maximum length, the minimum length, or the average value of the lengths of a plurality of line segments measured from one end to the other end of the embedded portion 202 in the second direction on the cross-section.

The widths d1 to d3 may be measured by an optical microscope or a scanning electron microscope. Other methods and/or tools appreciated by one of ordinary skill in the art, even if not described in the present disclosure, may also be used.

The embedded portion 202 and the protruding portion 201 may be formed by one-time plating. Accordingly, the central axes of the embedded portion 202 and the protruding portion 201 may coincide. Additionally, the embedded portion 202 and the protruding portion 201 may include the same material.

According to the circuit board according to this embodiment, by forming the upper portion of the protruding portion into a round shape, it is possible to reduce the risk of cracks on the pad and improve reliability. In addition, by forming uneven regions on the surface of the protruding portion in contact with the insulating layer and the surface of the embedded portion in contact with the insulating layer, it is possible to improve the adhesion between the insulating layer and the pad and reduce the risk of delamination defects. By forming the pad from a single piece of metal without an interface, the reliability of the pad may be strengthened.

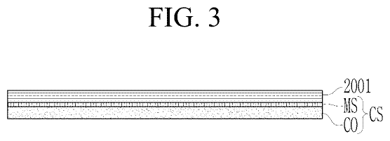

Hereinafter, a method of manufacturing a circuit board according to an embodiment will be described with reference to FIGS. 3 to 11. FIGS. 3 to 11 are cross-sectional views showing a method of manufacturing a circuit board according to an embodiment.

Referring to FIG. 3, a seed layer 2001 may be formed on a carrier substrate CS including a core portion CO and a thin film metal layer MS stacked on the core portion CO. The seed layer 2001 may be formed through a plating process. For example, the seed layer 2001 may include nickel. The thin metal layer MS may be formed of a material different from the seed layer 2001. The thin metal layer MS may include copper. The thin metal layer MS may include nickel with a composition different from that of the seed layer 2001.

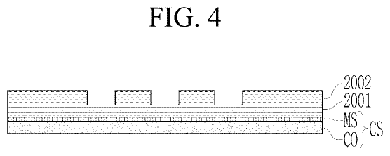

Referring to FIG. 4, a mask layer 2002 may be formed on the seed layer 2001. A portion excluding the region where the pad 200 (see FIG. 1) will be formed may be covered by the mask layer 2002. The mask layer 2002 may be formed including a dry film.

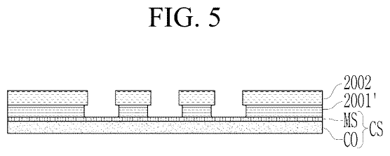

Referring to FIG. 5, a part of a seed layer 2001′ may be etched using the mask layer 2002 as an etch mask. For example, a part of the seed layer 2001′ may be etched using an etchant. In this case, the seed layer 2001′ and the thin metal layer MS may include metal materials that may be selectively removed by different etchants. As described above, for example, the seed layer 2001′ contains nickel, and the thin film metal layer MS may include copper. However, the present disclosure is not limited thereto.

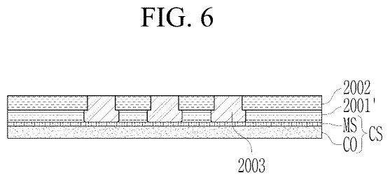

Referring to FIG. 6, a pad structure 2003 may be formed in the opening of the seed layer 2001′ and the mask layer 2002 through a plating process. For example, the pad structure 2003 may include copper.

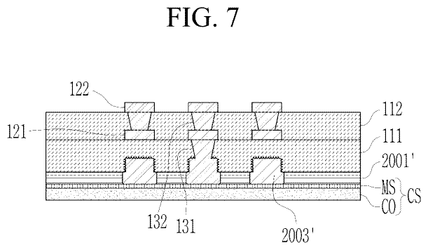

Referring to FIG. 7, a build-up structure may be formed by removing the mask layer 2002 and forming at least one insulating layer, at least one wiring layer, and at least one via layer on the seed layer 2001′. Here, roughness may be formed on the surface of a pad structure 2003′. In other words, the pad structure 2003′ may have uneven regions on the surface in contact with the mask layer 2002.

For example, the first insulating layer 111 may be formed to embed the pad structure 2003′. The first wiring layer 121 may be formed on the first insulating layer 111, and the first via layer 131 may be formed by penetrating at least a portion of the first insulating layer 111. Additionally, the second insulating layer 112 may be formed to embed the first wiring layer 121. The second wiring layer 122 may be formed on the second insulating layer 112, and the second via layer 132 may be formed by penetrating at least a part of the second insulating layer 112.

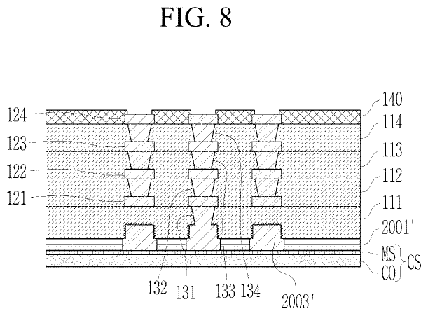

Referring to FIG. 8, a build-up structure may be formed by forming at least one insulating layer, at least one wiring layer, and at least one via layer on the second insulating layer 112. For example, the third insulating layer 113 may be formed to embed the second wiring layer 122. The third wiring layer 123 may be formed on the third insulating layer 113, and the third via layer may be formed by penetrating at least a part of the third insulating layer 113. Additionally, the fourth insulating layer 114 may be formed to embed the third wiring layer 123. A fourth wiring layer 124 may be formed on the fourth insulating layer 114, and the fourth via layer 134 may be formed through at least a part of the fourth insulating layer 114.

The solder resist layer 140 may be formed on one surface of the fourth insulating layer 114. The solder resist layer 140 may be formed to expose a part of the fourth wiring layer 124.

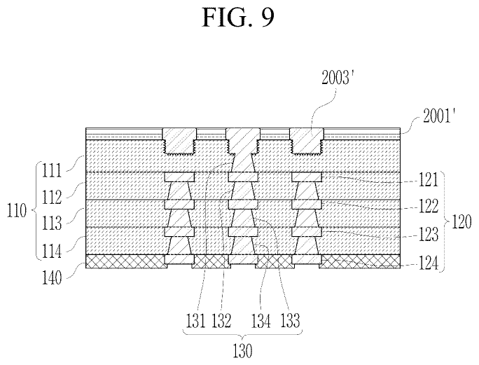

Referring to FIG. 9, the carrier substrate CS may be separated.

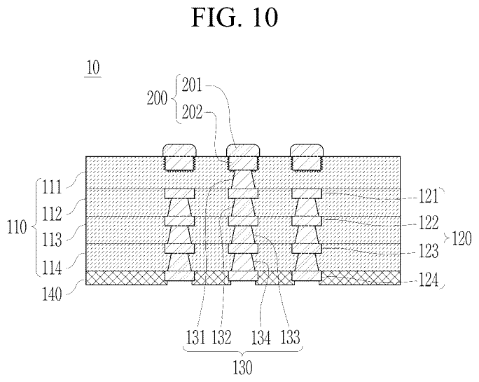

Referring to FIG. 10, the seed layer 2001 may be removed to form the pad 200 including the protruding portion 201 and the embedded portion 202.

Here, at least a part of the protruding portion 201 may be formed to have a round shape. For example, the corner region of the protruding portion 201 may be formed into a round shape through chemical etching such as soft etching. As another example, physical treatment, such as jet scrub, may be performed on the surface of the protruding portion 201 to form the corner region of the protruding portion 201 into a round shape.

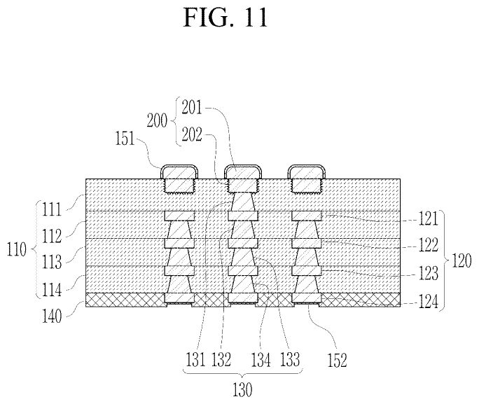

Referring to FIG. 11, the first surface treatment layer 151 may be formed on the surface of the protruding portion 201. Additionally, the circuit board 10 as shown in FIG. 1 may be formed by forming the second surface treatment layer 152 on the surface of the fourth wiring layer 124 exposed to the outside. For example, the first and second surface treatment layers 151 and 152 may be formed using organic solder ability preservative (OSP) or electroless nickel/electroless palladium/immersion gold (ENEPIG) methods. Additionally, as the surface treatment layer, a Ni/Pd/Au electroless plating layer or a Ni/Au electrolytic plating layer may be formed, but are not limited thereto. As the pad 200 contacts the insulating layer 110, formation of a surface treatment layer between the pad 200 and the insulating layer 110 may be prevented, and thus the adhesion of the pad 200 may be improved.

According to the method of manufacturing the circuit board according to the present embodiment, by forming the upper portion of the protruding portion into a round shape, it is possible to reduce the risk of cracks on the pad and improve reliability. In addition, by forming uneven regions on the surface of the protruding portion in contact with the insulating layer and the surface of the embedded portion in contact with the insulating layer, it is possible to improve the adhesion between the insulating layer and the pad and reduce the risk of delamination defects. By forming the entire pad shape with one-time plating, the reliability of the pad may be improved.

In addition, according to the method of manufacturing the circuit board according to the present embodiment, by forming a protruding pad without etching the insulating layer, it is possible to improve the adhesion between the pad and the insulating layer and achieve high reliability. In addition, by forming a protruding pad through etching, it is possible to reduce process costs, and freely design the pad according to the combination of the thickness of the seed layer and surface treatment.

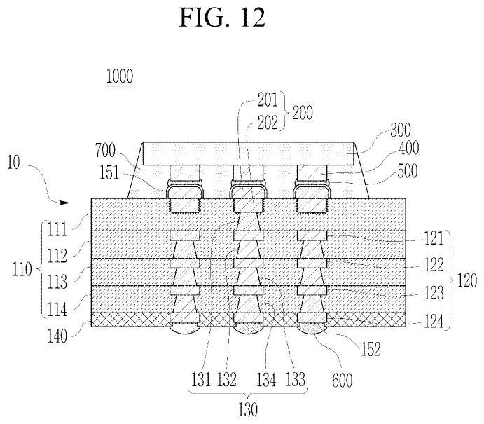

Hereinafter, with reference to FIG. 12, an electronic component package according to an embodiment will be described.

FIG. 12 is a cross-sectional view schematically showing an electronic component package according to an embodiment.

Referring to FIG. 12, an electronic component package 1000 according to the present embodiment may include the circuit board 10 according to the above-described embodiment. Hereinafter, the description of the circuit board may be applied in the same manner as the description of the circuit board 10 according to the above-described embodiment.

The electronic component package 1000 according to an embodiment may include a circuit board 10, an electronic component 300 mounted on one surface of the circuit board 10, a connecting portion 400 electrically connecting the circuit board 10 and the electronic component 300, a first conductive member 500 connecting the connecting portion 400 and the circuit board 10, a second conductive member 600 electrically connecting the circuit board 10 and a separate substrate or electronic component (not shown), and an underfill 700.

The electronic component 300 may be an integrated circuit (IC) die in which hundreds to millions of elements are integrated into one chip. For example, the electronic component 300 may be a processor chip, such as a central processor (for example, CPU), a graphics processor (for example, GPU), a field-programmable gate array (FPGA), a digital signal processor, an encryption processor, a microprocessor, a microcontroller, specifically an application processor (AP), but not limited thereto. In addition, the electronic component 300 may also be other volatile memories (for example, DRAM), non-volatile memories (for example, ROM), flash memories, or an analog-digital converter, or application-specific IC (ASIC) logic, or the like. If necessary, the electronic component 300 may be a chip-shaped passive component, for example, a chip-shaped capacitor such as a multi-layer ceramic capacitor (MLCC), a chip-shaped inductor such as a power inductor (PI), or the like.

The connecting portion 400 may be disposed between the electronic component 300 and the pad 200. The connecting portion 400 may electrically connect the electronic component 300 and the wiring layer 120. The connecting portion 400 may physically and/or electrically connect the electronic component 300 and the circuit board 10. For example, the connecting portion 400 may electrically connect the pad 200 to an exposed circuit of an electronic component.

The connecting portion 400 may be formed of copper or the like, but is not limited thereto. For example, the connecting portion 400 may be a pillar-shaped metal post, but is not limited thereto, and may have the shape of a land, ball, or pin.

The first conductive member 500 may be disposed on the first surface treatment layer 151. The first conductive member 500 may be formed of tin (Sn) or an alloy containing tin (Sn), for example, solder, etc., but is not limited thereto. For example, the first conductive member 500 may have a ball shape, but is not limited thereto, and may have a land, pin, or pillar-shaped metal post.

The second conductive member 600 may be disposed in at least a part of the opening of the solder resist layer 140. The second conductive member 600 may be positioned on the fourth wiring layer 124. The second conductive member 600 may physically and/or electrically connect the circuit board 10 to the outside. For example, the second conductive member 600 may electrically connect the exposed wiring layer of the circuit board 10 to an external substrate or electronic component. The second conductive member 600 may be formed of tin (Sn) or an alloy containing tin (Sn), for example, solder, etc., but is not limited thereto. For example, the first conductive member 500 may have a ball shape, but is not limited thereto, and may have a shape such as a land, a pin, or a pillar-shaped metal post.

The underfill 700 is a material filled between the electronic component 300 mounted on the circuit board 10 and the circuit board 10 and may fix the electronic component 300. In particular, when the connecting portion 400 protrudes and a gap is created between one surface of the electronic component 300 and the circuit board 10, the underfill 700 may be filled in the gap.

According to the electronic component package according to the present embodiment, by forming the upper portion of the protruding portion into a round shape, it is possible to reduce the risk of cracks on the pad and improve reliability. In addition, by forming uneven regions on the surface of the protruding portion in contact with the insulating layer and the surface of the embedded portion in contact with the insulating layer, it is possible to improve the adhesion between the insulating layer and the pad and reduce the risk of delamination defects. By forming the pad from a single piece of metal without an interface, it is possible to strengthen the reliability of the pad and reduce the thickness of the electronic component package by providing a highly reliable circuit board.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A circuit board, comprising:
an insulating layer burying at least one wiring layer and at least one via layer, the insulating layer having first and second surfaces facing each other in a first direction; and
a pad including a protruding portion protruding from the first surface of the insulating layer and an embedded portion embedded in the insulating layer, the pad electrically connecting to the wiring layer,
wherein the protruding portion comprises
a first portion positioned at an outermost part along the first direction and substantially parallel to a second direction that is parallel to the first surface; and
a second portion connected to the embedded portion and adjacent to the first surface, and
wherein along the second direction, a width of the first portion is different from a width of the second portion.

2. The circuit board of claim 1, wherein
the width of the first portion is smaller than the width of the second portion.

3. The circuit board of claim 1, wherein
the protruding portion further comprises a third portion connecting the first portion and the second portion,
and at least a part of the third portion has a round shape having a width that increases from the first portion to the second portion.

4. The circuit board of claim 3, wherein
at least a part of the third portion has a convex shape that curves outward of the protruding portion.

5. The circuit board of claim 1, wherein
the embedded portion comprises
a fourth portion positioned opposite the first portion of the protruding portion in the first direction and substantially parallel to the second direction; and
a fifth portion connecting the fourth portion and the protruding portion, and the fourth portion and the fifth portion are in contact with the insulating layer.

6. The circuit board of claim 5, wherein
the fourth portion and the fifth portion of the embedded portion have surface roughness.

7. The circuit board of claim 1, wherein
the second portion of the protruding portion comprises
a first region in contact with the insulating layer and a second region in contact with the embedded portion.

8. The circuit board of claim 7, wherein
the first region of the second portion of the protruding portion has surface roughness.

9. The circuit board of claim 1, wherein
central axes of the embedded portion and the protruding portion coincide.

10. The circuit board of claim 1, wherein
the embedded portion and the protruding portion include the same material.

11. An electronic component package, comprising:
an insulating layer burying at least one wiring layer and at least one via layer, the insulating layer having first and second surfaces facing each other in a first direction;
a pad including a protruding portion protruding from the first surface of the insulating layer and an embedded portion embedded in the insulating layer, the pad electrically connecting to the wiring layer; and
an electronic component disposed on the insulating layer and electrically connected to the pad,
wherein the protruding portion comprises
a first portion positioned at an outermost part along the first direction and substantially parallel to a second direction that is parallel to the first surface; and
a second portion connected to the embedded portion and adjacent to the first surface, and
wherein along the second direction, a width of the first portion is different from a width of the second portion.

12. The electronic component package of claim 11, wherein
the width of the first portion is smaller than the width of the second portion.

13. The electronic component package of claim 11, wherein
the protruding portion further comprises a third portion connecting the first portion and the second portion,
and at least a part of the third portion has a round shape having a width increasing from the first portion to the second portion.

14. The electronic component package of claim 13, wherein
at least a part of the third portion has a convex shape that curves outward of the protruding portion.

15. The electronic component package of claim 11, wherein
the embedded portion comprises
a fourth portion positioned opposite the first portion of the protruding portion in the first direction and substantially parallel to the second direction; and a fifth portion connecting the fourth portion and the protruding portion, and
the fourth portion and the fifth portion are in contact with the insulating layer.

16. The electronic component package of claim 15, wherein
the fourth portion and the fifth portion of the embedded portion have surface roughness.

17. The electronic component package of claim 11, wherein
the second portion of the protruding portion comprises
a first region in contact with the insulating layer and a second region in contact with the embedded portion.

18. The electronic component package of claim 17, wherein
the first region of the second portion of the protruding portion has surface roughness.

19. The electronic component package of claim 11, wherein
central axes of the embedded portion and the protruding portion coincide.

20. The electronic component package of claim 11, comprising
a connecting portion disposed between the electronic component and the pad to electrically connect the electronic component and the wiring layer.
